(19) United States
(12) Patent Application Publication
(10) Pub. No.: US 2017/0250332 A1
(43) Pub. Date: Aug. 31, 2017

(54) HEAT DISSIPATION FROM CIRCUITS THROUGH QUANTOM DOT OPTICS AND LED INTEGRATION

(71) Applicant: Thomas Paulos, Sherman Oaks, CA (US)

(72) Inventor: Thomas Paulos, Sherman Oaks, CA (US)

(21) Appl. No.: 15/441,536

(22) Filed: Feb. 24, 2017

Related U.S. Application Data
(60) Provisional application No. 62/299,800, filed on Feb. 25, 2016.
(60) Provisional application No. 62/330,974, filed on May 3, 2016.

(51) Int. Cl. H01L 33/64; H01L 33/58; H01L 33/56; H01L 33/50; H01L 33/62; H01L 33/60

(52) U.S. Cl. CPC H01L 33/647; H01L 33/62; H01L 33/60; H01L 33/56; H01L 33/502; H01L 33/58; H01L 2933/0075; H01L 2933/0066; H01L 2933/0058; H01L 2933/005; H01L 2933/0041; H01L 2933/0083

(57) ABSTRACT

A method is presented for forming a structure for dissipating heat. The method includes forming a first conductive material, forming a dielectric layer over the first conductive material, and forming a second conductive material over the dielectric layer such that the first and second conductive materials are coplanar along a longitudinal axis defined by a mounting surface of the first and second conductive materials. The method further includes attaching an electronic component to the mounting surface of the first and second conductive materials such that a first electrode of the electronic component electrically contacts the first conductive material and a second electrode of the electronic component electrically contacts the second conductive material.

### CROSS-REFERENCE TO RELATED APPLICATIONS

Applicants claim priority to provisional patent application Ser. No. 62/299,800 filed Feb. 25, 2016, entitled “LED Integration,” and provisional patent application Ser. No. 62/330,974 filed May 3, 2016, entitled “Quantum Dot Optics and LED Integration,” the entire contents of which are incorporated herein by reference.

### BACKGROUND

Technical Field

The present invention relates generally to heat dissipation from circuits.

Description of the Related Art

The electronics fabrication industry revolves around placing various electronic components onto circuits. The circuits are generally etched into singular or a plurality of layers on a printed circuit board (PCB), metal core printed circuit boards (MCPCB) boards, ceramic substrates and other functional equivalents. One issue facing electronics design is thermal management. It is common to use a dissipation device, such as a heat sink, for thermal cooling purposes in a circuit assembly. Traditionally, heat sinks are placed in direct contact with a device to prevent device overheating. The issue of using individual component heat sinks can be overcome by placing the entire PCB on a cooling surface such as a thermal pad. The thermal pad, or cold plate, acts as a heat sink, and individual components are on top of the board and heat dissipation paths go through the board to the pad, which is on the underside of the board. However, as the design space for electrical components is shrinking, more components are squeezed into a decreasing amount of space. The space required by all components becomes relevant and, particularly components are mounted close to other components.

### SUMMARY

In accordance with an embodiment, a method of forming a structure for dissipating heat is provided. The method includes forming a first conductive material, forming a dielectric layer over the first conductive material, forming a second conductive material over the dielectric layer such that the first and second conductive materials are coplanar along a longitudinal axis defined by a mounting surface of the first and second conductive materials, and attaching an electronic component to the mounting surface of the first and second conductive materials such that a first electrode of the electronic component electrically contacts the first conductive material and a second electrode of the electronic component electrically contacts the second conductive material.

In accordance with an embodiment, a method of forming a structure for dissipating heat is provided. The method includes forming a dielectric layer, forming a plurality of first conductive materials defining a first type of configuration on a first side of the dielectric layer, forming a plurality of second conductive materials defining a second type of configuration on a second side of the dielectric layer, where the second type of configuration is different than the first type of configuration, and attaching an electronic component to each of the plurality of first and second conductive materials such that a first electrode of the electronic component electrically contacts a first conductive material and a second electrode of the electronic component electrically contacts a second conductive material on opposed ends of the dielectric layer.

In accordance with another embodiment, a structure for dissipating heat is provided. The semiconductor device includes a first conductive material, a dielectric layer formed over the first conductive material, a second conductive material formed over the dielectric layer such that the first and second conductive materials are coplanar along a longitudinal axis defined by a mounting surface of the first and second conductive materials, and an electronic component attached to the mounting surface of the first and second conductive materials such that a first electrode of the electronic component electrically contacts the first conductive material and a second electrode of the electronic component electrically contacts the second conductive material.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE SEVERAL VIEWS OF THE DRAWINGS

The invention will provide details in the following description of preferred embodiments with reference to the following figures wherein:

FIG. 1A is a cross-sectional view of a conventional structure for mounting a component onto a circuit board;

FIG. 1B is a cross-sectional view of a structure for mounting a component directly on conductive materials thereof, in accordance with an embodiment of the present invention;

FIG. 2A is a perspective view of a structure including conductive materials which flank a dielectric layer, in accordance with an embodiment of the present invention;

FIG. 2B is a perspective view of the structure of FIG. 2A where an electrical component is attached thereto, in accordance with an embodiment of the present invention;

FIG. 2C is a top view of the structure of FIG. 2B depicting the component attached to the structure, in accordance with an embodiment of the present invention;

FIG. 2D is an enlarged view of FIG. 2C where the first and second electrodes of the component are shown, in accordance with an embodiment of the present invention;

FIG. 3A is a perspective view of a structure including conductive materials which flank a dielectric layer, the structure including a plurality of electronic components extending across a top surface thereof, as well as an example reflector surrounding an electronic component, in accordance with another embodiment of the present invention;

FIG. 3B is a perspective view of a plurality of structures of FIG. 3A in a stacked configuration, in accordance with another embodiment of the present invention;

FIG. 3C is a perspective view of a plurality of structures of FIG. 3A arranged in a staggered array, in accordance with another embodiment of the present invention;

FIG. 3D is a top view of FIG. 3C illustrating the plurality of structures arranged in a staggered array, in accordance with an embodiment of the present invention;

FIG. 4 is a top view of the structure of FIG. 2B illustrating the first electrode contacting one conductive material and the second electrode contacting the other conductive material, in accordance with an embodiment of the present invention;

FIG. 5 is an exploded view of the structure of FIG. 2A illustrating the deposition of one or more conducting/metallic layers, in accordance with an embodiment of the present invention;

FIG. 6 is a perspective view of a structure including conductive materials which flank a dielectric layer, the conductive materials having interconnects for electrification of the module, in accordance with another embodiment of the present invention;

FIG. 7A is a perspective view of a structure including conductive materials which flank a dielectric layer, the conductive materials being offset from each other, in accordance with another embodiment of the present invention;

FIG. 7B is a perspective view of the structure of FIG. 7A where an electronic component is attached to a portion of a top surface of the conductive materials, in accordance with an embodiment of the present invention;

FIG. 7C is a perspective view of the structure of FIG. 7B where a reflective cavity is formed around the electronic component, in accordance with an embodiment of the present invention;

FIG. 7D is a perspective view of the structure of FIG. 7C where a reflective material is included within the reflective cavity, in accordance with an embodiment of the present invention;

FIG. 7E is a perspective view of structures of FIGS. 7C and 7D attached to a printed circuit board (PCB), in accordance with an embodiment of the present invention;

FIG. 8A is a perspective view of conductors attached to a dielectric layer in a first type of configuration, in accordance with an embodiment of the present invention;

FIG. 8B is a top view of the conductors of FIG. 8A attached to a dielectric layer in the first type of configuration, where electronic components are attached thereto, in accordance with an embodiment of the present invention;

FIG. 9A is a side view of a series of conductors mounted on a dielectric layer in a first type of configuration, in accordance with an embodiment of the present invention;

FIG. 9B is a side view of a series of conductors mounted on a dielectric layer in a first type of configuration, where a bus enables separation of components into one or more groups, in accordance with an embodiment of the present invention;

FIG. 9C is an enlarged view of a section of the bus, as well as an opening formed on the bus and openings formed on the conductors, in accordance with an embodiment of the present invention;

FIG. 9D is a perspective view of a plurality of structures of FIG. 9B formed in a stacked configuration, in accordance with an embodiment of the present invention;

FIG. 10 is a perspective view of the structure of FIG. 9B encased within a reflective material structure including a photoluminescent material section, in accordance with an embodiment of the present invention;

FIG. 11 is a perspective view of the structure of FIG. 10 in communication with a light guide, in accordance with an embodiment of the present invention;

FIG. 12 is a top view of the structure of FIG. 10 where a plurality of reflective cavities are formed to separate the components from each other to produce a plurality of colors without cross talk, in accordance with an embodiment of the present invention;

FIG. 13 is a top view of the structure of FIG. 12 where the plurality of reflective cavities are attached to a light guide, in accordance with an embodiment of the present invention;

FIG. 14 is a perspective, cut-away view of the structure of FIG. 12 where each of the plurality of reflective cavities includes a component for generating different colors without cross talk, in accordance with an embodiment of the present invention;

FIG. 15 is a perspective view of an example optical structure, in accordance with an embodiment of the present invention;

FIG. 16A is an exploded view of a hermetically sealed quantum dot dispersed in an optically transmissive material, in accordance with an embodiment of the present invention;

FIG. 16B is a perspective assembled view of the hermetically sealed quantum dot dispersed in an optically transmissive material of FIG. 16A, in accordance with an embodiment of the present invention; and

FIG. 16C is a cross-sectional view of the hermetically sealed quantum dot dispersed in an optically transmissive material, in accordance with an embodiment of the present invention.

Throughout the drawings, same or similar reference numerals represent the same or similar elements.

### DETAILED DESCRIPTION

In one or more exemplary embodiments, a substrate which reduces thermal resistance between a given component and its circuit is presented. The substrate may also serve as a way to electrify electrical components which are mounted thereon. In one example embodiment, an electrical component, e.g., a light emitting diode (LED) is mounted directly onto the substrate. However, this is not a limiting electronic component as other electronic components requiring heat dissipation may be mounted thereof.

In one or more exemplary embodiment, the substrate is designed to accommodate eutectic attach die where substantially coplanar electrodes are lined up on the substrate. These die are usually bonded via, e.g., thermal processes. However, this is not a limiting example, as other functionally equivalent processes for attaching components may exist, such as, but not limited to, ultrasonic bonding. Other methods, such as soldering can also be used, which requires less coplanarity.

In one or more embodiments, a dielectric layer is flanked between a first conductive material and a second conductive material to form a structure. The first and second conductive materials can be copper (Cu) materials. The first and second conductive materials can be offset from each other along a mounting surface. An electronic component is attached to the structure such that first and second electrodes of the electronic component are coplanar with the mounting surface of the first and second conductive materials. The electronic component can be, e.g., a light emitting diode (LED). The electronic components can interfaced with, e.g., a quantum dot matrix or a phosphor matrix. The quantum dot can include, e.g., a protective aluminum oxide shell.

In one or more embodiments, a reflective cavity including a photoluminescent material therein can be incorporated to surround the electronic component or light emitting device. The reflective cavity allows for directing light in one direction toward, e.g., a lens to produce one or more colors.

In one or more embodiments, a plurality of first conductive materials can be formed on one side of a dielectric layer and a plurality of second conductive materials can be formed on another side of the dielectric layer to form another structure. The first and second sides may be in opposed relation to each other. The plurality of first and second conductive materials can be arranged in a number of different types of configurations. One such example configuration can be an angled configuration. However, one skilled in the art may contemplate other suitable configurations. A bus can be formed on the dielectric layer such that the plurality of first conductive materials can be grouped into a number of first groups and the plurality of second conductive materials can be grouped into a number of second groups. The structure can be encased within a reflective material such that a reflective cavity is defined. The reflective cavity can be defined in such a way to interface with the electronic components (e.g., light emitting devices) including a photoluminescent material. In one example, the reflective material encasing the structure can be integrated with, e.g., a light guide.

The term “color” as used herein with reference to light is meant to describe light having a characteristic average wavelength. It is not meant to limit the light to a single wavelength. Thus, light of a particular color (e.g., green, red, blue, yellow, etc.) includes a range of wavelengths that are grouped around a particular average wavelength.

The term “direct contact” or “directly on” means that a first element, such as a first structure, and a second element, such as a second structure, are connected without any intermediary conducting, insulating or semiconductor layers at the interface of the two elements.

The terms “overlying”, “atop”, “positioned on” or “positioned atop” means that a first element, such as a first structure, is present on a second element, such as a second structure, wherein intervening elements, such as an interface structure can be present between the first element and the second element.

The term “electrically connected” means either directly electrically connected, or indirectly electrically connected, such that intervening elements are present; in an indirect electrical connection, the intervening elements can include inductors and/or transformers.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

The terms, chip, integrated circuit, monolithic device, semiconductor device, and microelectronic device, are often used interchangeably in this field. The present invention is applicable to all the above as they are generally understood in the field.

The terms metal line, interconnect line, trace, wire, conductor, signal path and signaling medium are all related. The related terms listed above, are generally interchangeable, and appear in order from specific to general. In this field, metal lines are sometimes referred to as traces, wires, lines, interconnect or simply metal. Metal lines, generally aluminum (Al), copper (Cu) or an alloy of Al and Cu, are conductors that provide signal paths for coupling or interconnecting electrical circuitry. Conductors other than metal are available in microelectronic devices. Materials such as doped polysilicon, doped single-crystal silicon (often referred to simply as diffusion, regardless of whether such doping is achieved by thermal diffusion or ion implantation), titanium (Ti), molybdenum (Mo), and refractory metal silicides are examples of other conductors.

The term “processing” as used herein includes deposition of material or photoresist, patterning, exposure, development, etching, cleaning, stripping, implanting, doping, stressing, layering, and/or removal of the material or photoresist as required in forming a described structure.

As used herein, a surface is “substantially planar” if the surface is intended to be planar and the non-planarity of the surface is limited by imperfections inherent in the processing steps that are employed to form the surface.

As used herein, a “mounting structure” is any structure to which a semiconductor chip can be mounted by making electrical connections thereto. A mounting structure can be a packaging substrate, an interposer structure, or another semiconductor chip or any other electronic component.

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this invention.

The present subject matter will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

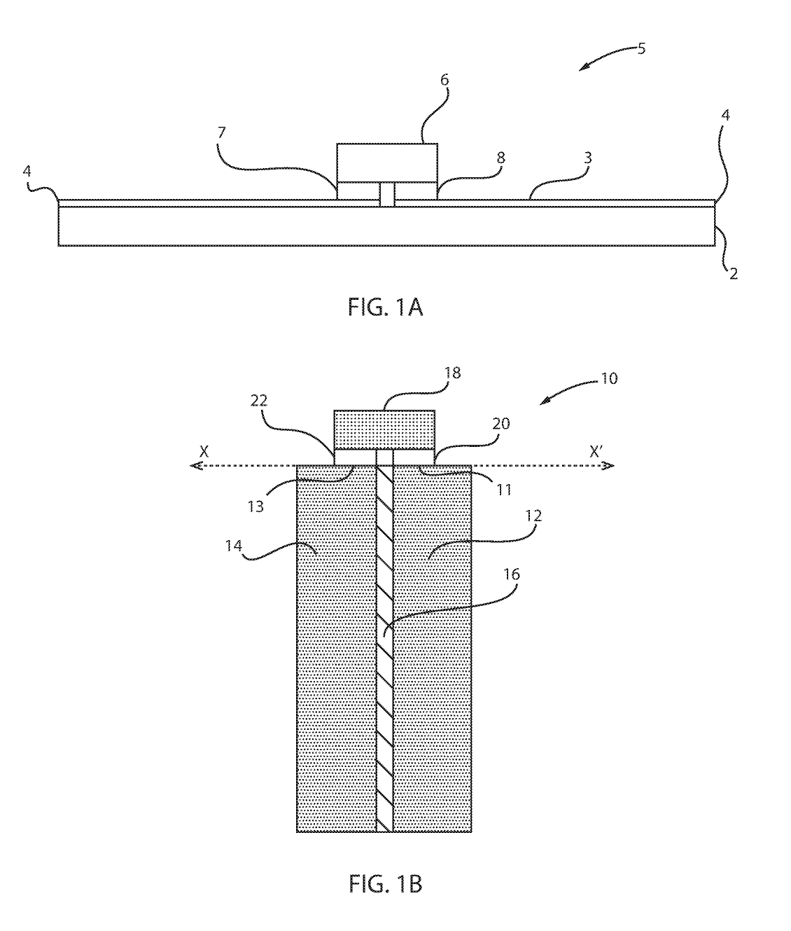

FIG. 1A is a cross-sectional view of a conventional structure for mounting a component onto a circuit board.

The structure 5 includes a conductive layer 4 formed over a dielectric layer 2. An electronic component 6 is mounted to the top surface 3 of the conductive layer 4 by a first electrode 7 and a second electrode 8. The electronic component 6 is, e.g., a heat generating electronic component. The conductive layer 4 is e.g., a circuit conductor. The dielectric layer 2 can be, e.g., FR4, ceramic or any other type of dielectric material.

The dielectric layer 2 introduces thermal resistance to the electronic component 6. Generally, electrodes 7, 8 are configured to be close to one another, thus introducing dimensional constrains to the placement of bond pads (not shown) on a given printed circuit board (PCB). Due to fabrication limitations of etching patterns or circuits onto these PCB's or other circuits, the overall thickness of pads is limited. Because of these limitations, these conductors are not able to serve as effective heat spreaders, heatsinks or thermal dissipators.

FIG. 1B is a cross-sectional view of a structure for mounting a component directly on conductive materials thereof, in accordance with an embodiment of the present invention.

The structure 10 includes a first conductive material 12, a second conductive material 14, and a dielectric layer 16 sandwiched between the first and second conductive materials 12, 14. Stated differently, the first and second conductive materials 12, 14 flank the dielectric layer 16. The first conductive material 12 can have a thickness substantially equal to the thickness of the second conductive material 14. Alternatively, the first conductive material 12 can have a thickness that is not equal to the thickness of the second conductive material 14. The first and second conductive materials 12, 14 can have a thickness that is greater than the thickness of the dielectric layer 16. In one example embodiment, the first and second conductive materials 12, 14 can be copper (Cu) or aluminum (Al). Of course, one skilled in the art may contemplate using any other suitable materials.

An electronic component 18 is attached or connected or bonded to the first and second conductive materials 12, 14. In particular, the electronic component 18 includes a first electrode 20 and a second electrode 22. The first electrode 20 is connected or bonded or attached to the first conductive material 12, whereas the second electrode 22 is connected or bonded or attached to the second conductive material 14. A top surface 11 of the first conductive material 12 contacts or engages a bottom surface of the first electrode 20. Similarly, a top surface 13 of the second conductive material 14 contacts or engages a bottom surface of the second electrode 22. The first electrode 20 can be referred to as an anode and the second electrode 22 can be referred to as a cathode, and vice versa.

The top surfaces 11, 13 of the first and second conductive materials 12, 14 are substantially coplanar in order to facilitate alignment of the electrodes 20, 22. Stated differently, the first and second conductive materials 12, 14 are coplanar along a longitudinal axis X-X′ defined by mounting surfaces 11, 13 of the first and second conductive materials 12, 14 (as well as an axis Y-Y′). In other words, the top surfaces of the conductive materials 12, 14 are coplanar with the bottom surfaces of the electrodes 20, 22, respectively. The coplanarity of the two surfaces 11, 13 can be, e.g., within or less than about 1 μm. In a preferred embodiment, the two surfaces 11, 13 can be, e.g., within or less than about 3 μm. In another example embodiment, the coplanarities can range from about 1 μm to about 50 μm. Additionally, coplanar refers to both conductive materials 12, 14 being planar with respect to each other. The coplanarity can be exhibited on any mounting surface and is not limited to surfaces 11, 13. This is merely an illustrative example.

By mounting the electrodes 20, 22 directly on the conductive materials 12, 14, respectively, substantial reduction of thermal resistance is realized. The conductive materials 12, 14 can be substantially thick, thus providing heat spreading, heat-sinking, and thermal dissipation capabilities while also electrifying components. This methodology allows for enhanced thermal dissipation while electrifying the electrical/electronic component 18. One additional benefit is that the conductive materials 12, 14 can serve as convecting surfaces to dissipate heat into surrounding fluids, such as gases or liquids.

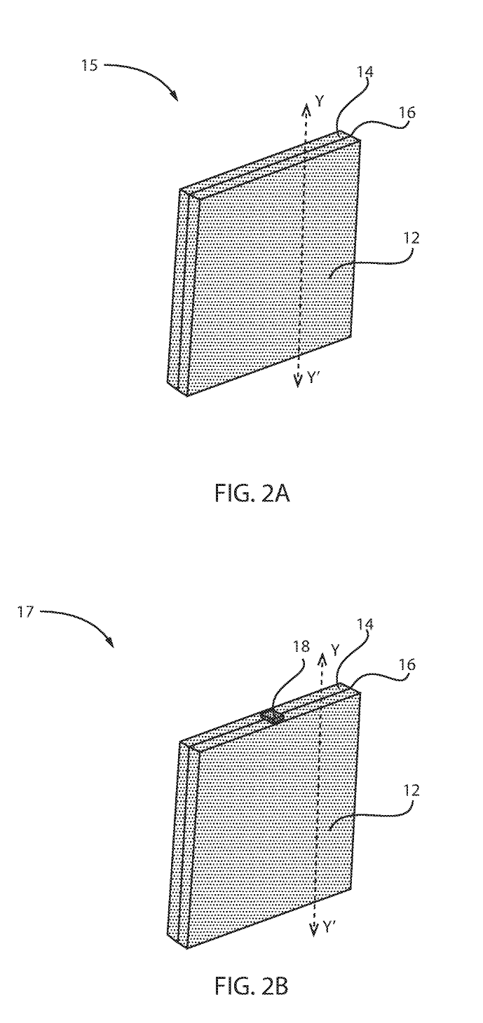

FIG. 2A is a perspective view of a structure including conductive materials which flank a dielectric layer, in accordance with an embodiment of the present invention.

In various example embodiments, a structure 15 includes a first conductive material 12, a second conductive material 14, and a dielectric layer 16, where the dielectric layer 16 is flanked by the first and second conductive materials 12, 14.

FIG. 2B is a perspective view of the structure of FIG. 2A where an electrical component is attached thereto, in accordance with an embodiment of the present invention.

In various example embodiments, an electronic component 18 is attached on a side surface of the structure 15, thus resulting in structure 17. The electronic component 18 can be attached or bonded or connected or mounted on any side surface of the structure 17. The electronic component 18 can be centrally disposed with respect to the dielectric layer 16. Of course, one skilled in the art may contemplate attaching the electronic component 18 on any location of the side surface of structure 17, whether centered or not. Additionally, a longitudinal axis Y-Y′ can extend through the structures 15, 17.

In one example embodiment, the electronic component 18 can be, e.g., a light emitting diode (LED) or a laser diode. Of course, one skilled in the art may contemplate any type of light emitting device serving as the light emitting device 18.

FIG. 2C is a top view of the structure of FIG. 2B depicting the component attached to the structure, in accordance with an embodiment of the present invention.

In various example embodiments, the electronic component 18 is shown attached to a side surface 19 of the structure 17 of FIG. 2B. The electronic component 18 extends onto a surface of the first conductive material 12 and extends onto a surface of the second conductive material 14. The electronic component 18 also extends over the dielectric layer 16.

FIG. 2D is an enlarged view of FIG. 2C where the first and second electrodes of the component are shown, in accordance with an embodiment of the present invention.

In various example embodiments, the electrodes 20, 22 are shown with respect to the first and second conductive materials 12, 14. The first electrode 20 extends a distance X₁ over the mounting surface 11 (FIG. 1B) of the first conductive material 12 and the second electrode 22 extends a distance X₂ over the mounting surface 13 (FIG. 1B) of the second conductive material 14. The first and second conductive materials 12, 14 can have a width “W.” The electronic component 18 can be centrally disposed on the side surface of structure 17. However, one skilled in the art can contemplate any placement of the electrical component 18 on side surfaces of the structure 17.

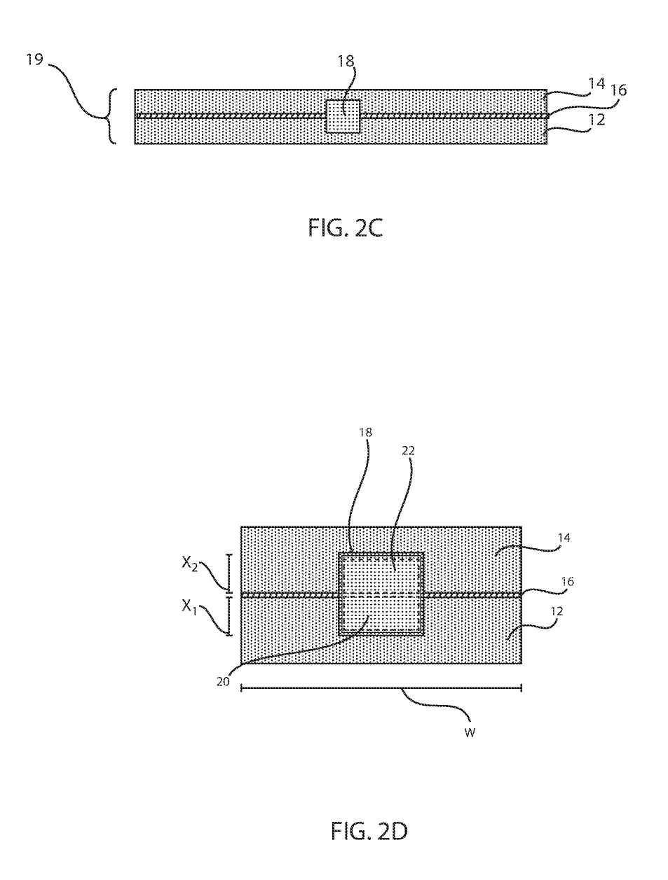

FIG. 3A is a perspective view of a structure including conductive materials which flank a dielectric layer, the structure including a plurality of electronic components extending across a top surface thereof, as well as an example reflector surrounding an electronic component, in accordance with another embodiment of the present invention.

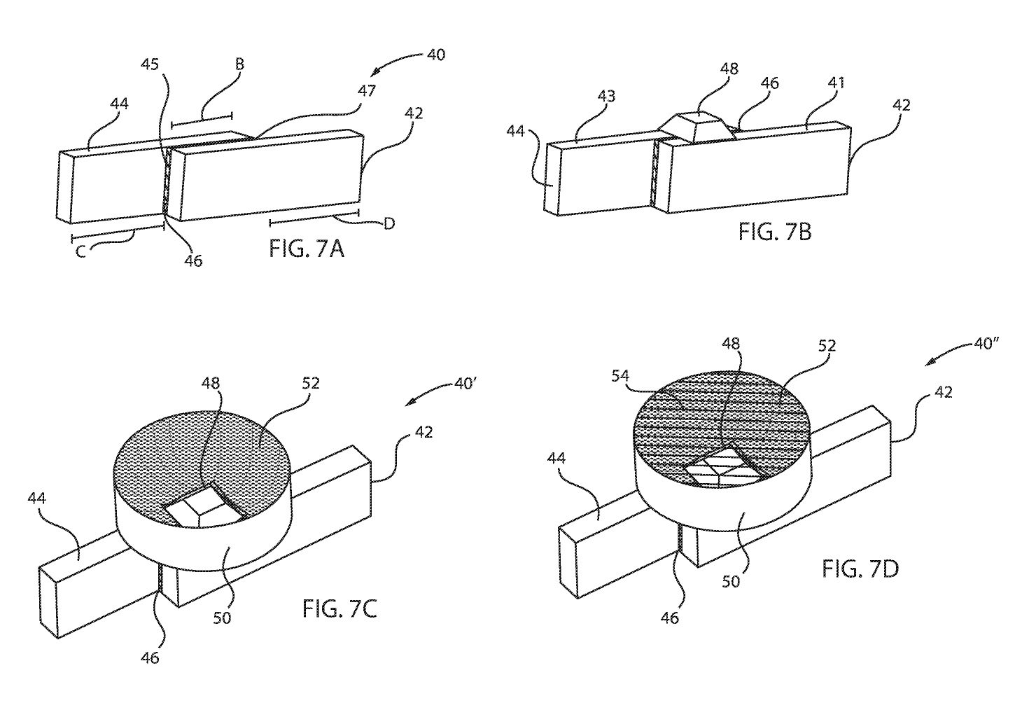

In various example embodiments, a plurality of electronic components 18 can be attached to a side surface 19 of the structure 21. Additionally, a reflective cavity 50 including a photoluminescent material 52 filled or coated thereto can be formed around or surrounding one or more electronic components 18. The reflective cavity 50 will be described in more detail below with reference to FIGS. 7A-7D. The plurality of components 18 can be attached or mounted to any side surface of the structure 21 (including all side surfaces). One skilled in the art may contemplate mounting any number of electronic components 18 on any side surface of the structure 21.

FIG. 3B is a perspective view of a plurality of structures of FIG. 3A in a stacked configuration, in accordance with another embodiment of the present invention.

In various example embodiments, the structure 21 of FIG. 3A can be formed in a stacked configuration 10′. In other words, multiple structures 21 can be stacked on top of each other to form structure 10′. A plurality of electronic components 18 can be aligned upon completion of stacking structure 18. The stack 10′ can have a thickness 24. In the instant case, the thickness represents a stack of three (3) structures 21. Of course, one skilled in the art can contemplate a number of structures 21 stacked on top of each other.

FIG. 3C is a perspective view of a plurality of structures of FIG. 3A arranged in a staggered array, in accordance with another embodiment of the present invention, whereas FIG. 3D is a top view of FIG. 3C illustrating the plurality of structures arranged in a staggered array, in accordance with an embodiment of the present invention.

In various example embodiments, a staggered array 10″ can be formed. In the staggered array 10″, the first conductive material 12 is offset from the second conductive material 14. The first conductive material 12 can extend a length L1, whereas the second conductive material 14 can extend a length L2. An overlap region can be created by lengths L1 and L2. Additionally, gaps 26 are formed due to the formation of the staggered array 10″. The gaps 26 can extend a length L3. The gaps 26 are created for cooling purposes.

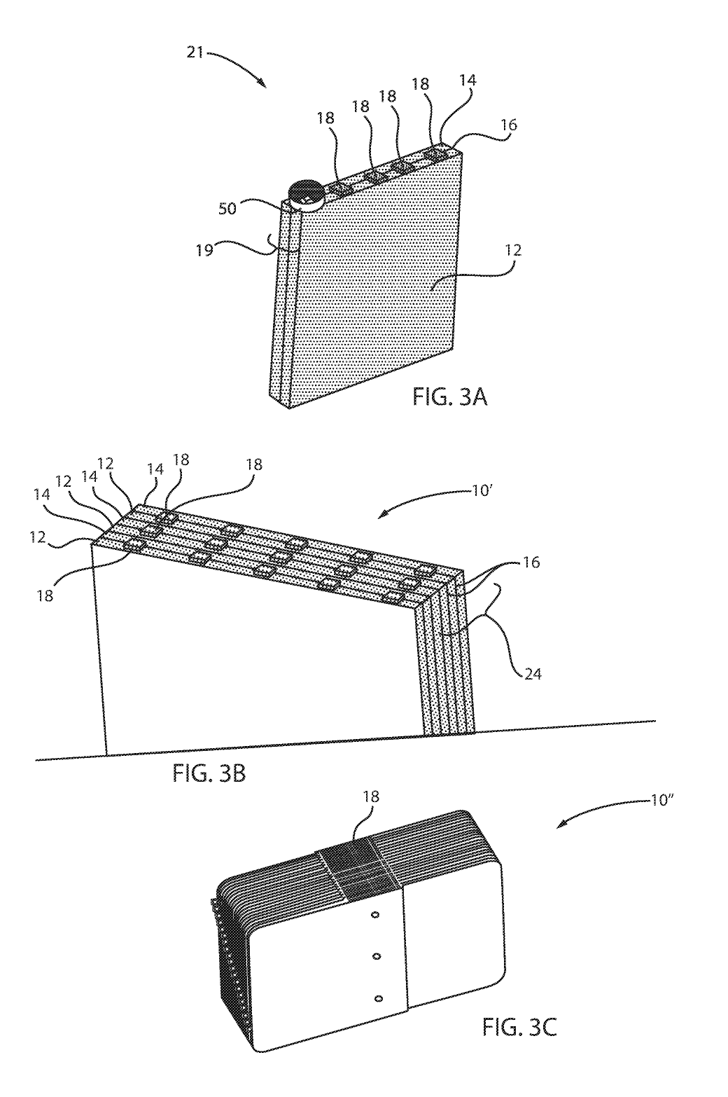

FIG. 4 is an enlarged top view of the structure of FIG. 2B illustrating the first electrode contacting one conductive material and the second electrode contacting the other conductive material, in accordance with an embodiment of the present invention.

In various example embodiments, an enlarged view of the electronic component 18 is shown to illustrate the electrodes 20, 22 formed underneath. The first electrode 20 extends a distance X₁ over the mounting surface 11 of the first conductive material 12 and the second electrode 22 extends a distance X₂ over the mounting surface 13 of the second conductive material 14.

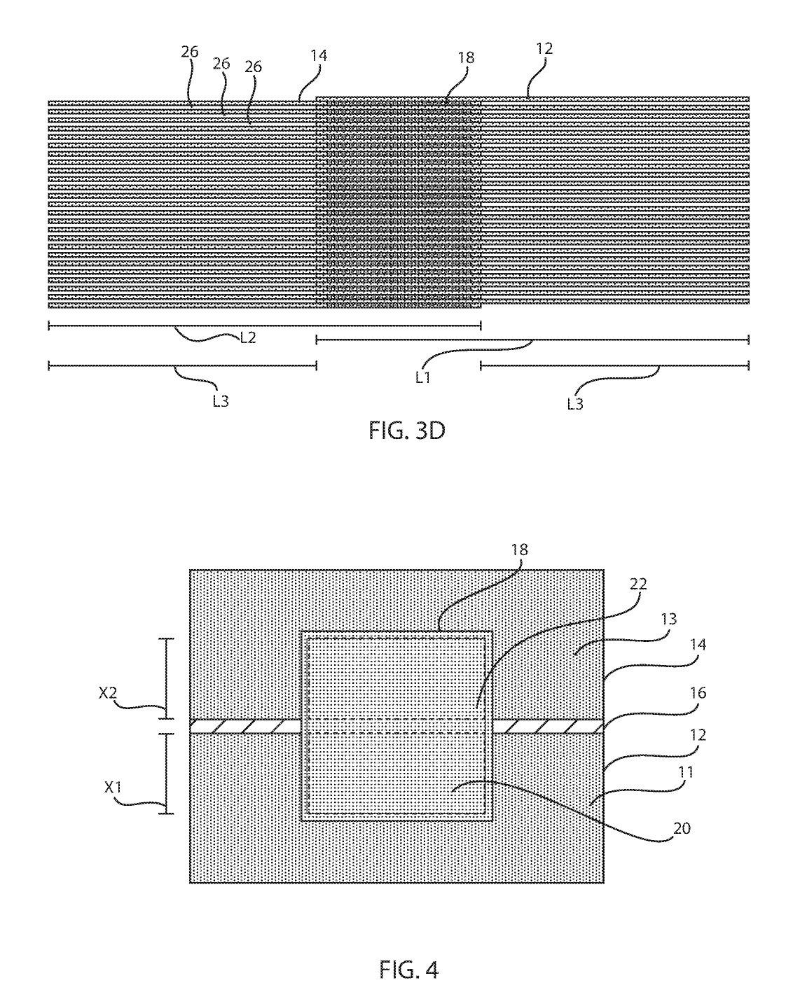

FIG. 5 is an exploded view of the structure of FIG. 2A illustrating the deposition of one or more conducting/metallic layers, in accordance with an embodiment of the present invention.

In various example embodiments, a side surface of structure 15 of FIG. 2A can include one or more conducting layers 30, 32. Conducting layers 30, 32 can be, e.g., metallic layers. Metallic layer 30 can be, e.g., a nickel (Ni) plating and metallic layer 32 can be, e.g., a gold (Au) plating. Of course, one skilled in the art may contemplate the use of any type of conducting material to form layers 30, 32. The exemplary embodiments described herein are not limited to only Ni and Au. In fact, the layers 30, 32 can be composed of alloys. The layers 30, 32 can be deposited by any means, such as, but not limited to sputtering.

One skilled in the art may also contemplate using more than two conducting layers. Moreover, one or more electronic components 18 can be attached to the conducting layers 30, 32. Thus, the conducting layers 30, 32 are formed between the side surface of the structure 15 and one or more electronic components 18 attached thereto. It is also contemplated that more than one side surface of structure 15 includes conducting layers 30, 32. For example, two side surfaces of the structure 15 can be configured to receive the conducting layers 30, 32. These surfaces may be adjacent surfaces or opposed surfaces. Of course, even all surfaces may be configured to receive conducting layers 30, 32. The conducting layers 30, 32 can extend along an entire or partial side surface of the structure 15. The structure 15 can have a width “W” and a height “H.” Thus, in one example, the conducting layers 30, 32 can extend along an entire width “W” or height “H” of the side surfaces of the structure 15.

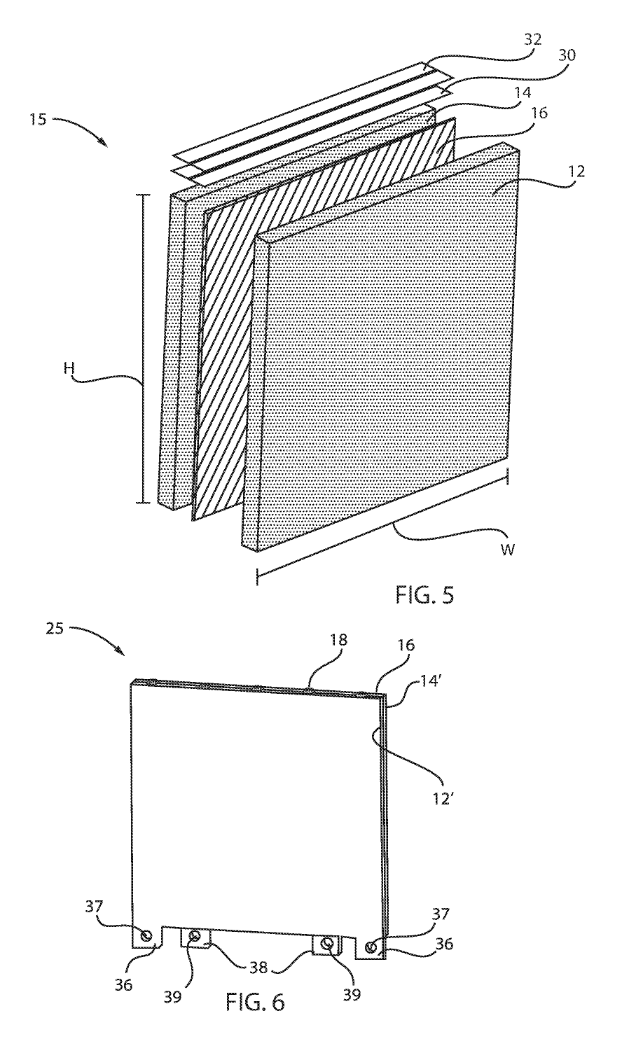

FIG. 6 is a perspective view of a structure including conductive materials which flank a dielectric layer, the conductive materials having interconnects for electrification of the module, in accordance with another embodiment of the present invention.

In various example embodiments, a structure 25 can be formed by flanking a dielectric layer 16 between a first conductive material 12′ and a second conductive material 14′. The first conductive material 12′ may include one or more interconnects 36. Interconnects 36 can be, e.g., protruding tabs. The interconnects 36 can also each include an aperture or opening 37. The second conductive material 14′ may include one or more interconnects 38. Interconnects 38 can be, e.g., protruding tabs. The interconnects 38 can also each include an aperture or opening 39. The interconnects 36 can be offset from the interconnects 38. The interconnects 36, 38 aid in the electrification of electrical components 18.

FIG. 7A is a perspective view of a structure including conductive materials which flank a dielectric layer, the conductive materials being offset from each other, in accordance with another embodiment of the present invention.

In various example embodiments, a structure 40 can include a first conductive material 42 that is offset from a second conductive material 44. A dielectric layer 46 is disposed between a section where the first and second conductive materials 42, 44 overlap. The dielectric layer 46 can extend a distance “B” from a first end 45 to a second end 47. The first conductive material 42 can extend a distance “D” away from the dielectric layer 46, whereas the second conductive material 44 can extend a distance “C” away from the dielectric layer 46. The offset creates a longer heat path. Stated differently, the heat generated by the electronic component 48 can be spread across a greater surface. Thus, the first and second conductive materials 42, 44 can be referred to as convecting surfaces.

FIG. 7B is a perspective view of the structure of FIG. 7A where an electronic component is attached to a portion of a top surface of the conductive materials, in accordance with an embodiment of the present invention.

In various example embodiments, an electronic component 48 is attached or connected or bonded to the top surfaces 41, 43 of the first and second conductive materials 42, 44, respectively. The electronic component 48 can be, e.g., centered over the dielectric layer 46 such that the electronic component 48 substantially equally contacts or engages the top surfaces 41, 43 of the first and second conductive materials 42, 44, respectively.

FIG. 7C is a perspective view of the structure of FIG. 7B where a reflective cavity is formed around the electronic component, in accordance with an embodiment of the present invention.

In various example embodiments, a reflective cavity 50 is formed around or surrounding the electronic component 48. The reflective cavity 50 can have, e.g., a substantially circular configuration. Of course, the reflective cavity 50 can be arranged in a variety of other suitable shapes. The reflective cavity 50 can further have a photoluminescent material 52 therein. The photoluminescent material 52 can be, e.g., coated or deposited by any manner. The photoluminescent material 52 can be positioned, e.g., by a fill technique. The final structure can be designated as 40′.

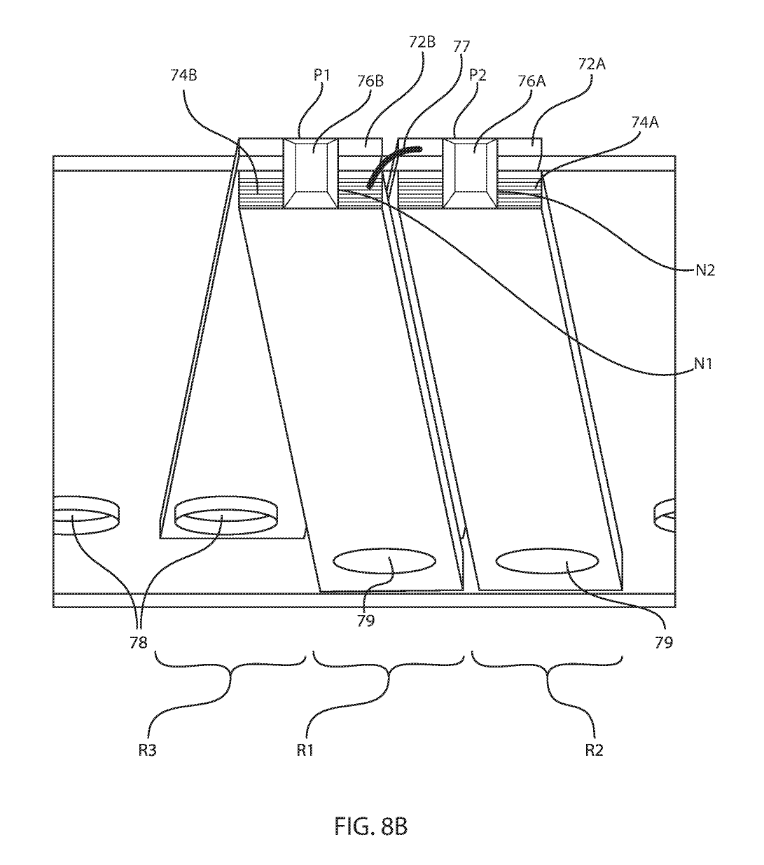

The photoluminescent material 52 can be, e.g., a quantum dot or a phosphor, as described below. The reflective cavity 50 can be referred to as an optical cavity having reflective properties for assisting in reflecting light in the context of light emitting devices. The reflective materials 52 can include, but are not limited to, multi-layer polymer films, metallized polymers, polished metals, a distributed Bragg reflector, white surfaces or other functional equivalents. Each reflective cavity 50 can be standalone cavity or can be configured in an array of row columns or other patterns. The reflective cavities 50 can be formed, stamped, injection molded, printed or assembled from separate components. Each reflective cavity 50 can include a single LED or a plurality of LEDs. Each reflective cavity 50 can include a quantum dot matrix or a phosphor matrix. Matrices are defined as optical materials including a dispersion of quantum dots (nano-semiconductor crystals or rare earth phosphors). Optical materials can further include polymers, such as acrylics, ultraviolet (UV) cured materials, silicones or other optically transmissive materials. Reflective cavities 50 and reflective materials 52 will be discussed further below with reference to FIGS. 10-15.

Moreover, high refractive index materials, such as titanium dioxide, cubic zirconium or other functional equivalents can be added to the optical matrix to enhance light extraction from the electrical component 48. By more closely increasing the refractive index of the matrix interfacing the chip to match the refractive index of the chip, a reduction of total internal reflection in the chip occurs, thus allowing more light to escape a boundary layer of the electronic component 48 and travel into the optical matrix, which includes down converting materials, such as quantum dots and phosphors.

FIG. 7D is a perspective view of the structure of FIG. 7C where a reflective material is included within the reflective cavity, in accordance with an embodiment of the present invention.

In various example embodiments, a hermetic seal 54 can be included over the electronic component 48. The hermetic seal 54 can extend along the entire portion of the reflective cavity 50 such that it seals the entire contents of the reflective cavity 50. Thus, the quantum dots or phosphors can be hermetically sealed or encapsulated within the reflective cavity 50. The final structure including the seal 54 can be designated as 40″.

FIG. 7E is a perspective view of structures of FIGS. 7C and 7D attached to a printed circuit board (PCB), in accordance with an embodiment of the present invention.

In various example embodiments, the structures 40′, 40″ can be mounted onto a circuit board 68 to create series circuits and/or parallel circuits 60. The circuit board 68 can include a plurality of pads. For example, pads 62, 64, 66 can be formed onto the circuit board 68 to enable electrical connection between the structures 40′, 40″, which include a plurality of photoluminescent materials, such as LEDs or down-converting quantum dots or phosphors.

Light emitting diodes (LED or LEDs) are solid state devices that convert electric energy to light, and generally comprise one or more active layers of semiconductor material sandwiched between oppositely doped layers. When a bias is applied across the doped layers, holes and electrons are injected into the active layer where they recombine to generate light. Light is emitted from the active layer and from all surfaces of the LED.

Light that is perceived as white is necessarily a blend of light of two or more colors (or wavelengths), and light emitting diodes are inherently narrow-band emitters. No single light emitting diode junction has been developed that can produce white light. A representative example of a white LED lamp or LED package includes a blue LED chip (e.g., made of InGaN and/or GaN), coated with a broad-band emitter, such as phosphor (typically YAG:Ce or BOSE). A broad-band emitter generally has an emission pattern with an approximate full width half maximum (FWHM) greater than 100 nm. Blue LEDs made from InGaN exhibit high efficiency (e.g., external quantum efficiency as high as 70%). In a blue LED/yellow phosphor lamp, a blue LED chip may produce an emission with a wavelength of about 450 nm, and the phosphor may produce yellow fluorescence with a peak wavelength of about 550 nm upon receipt of the blue emission. Part of the blue ray emitted from the blue LED chip passes through the phosphor, while another portion of the blue ray is absorbed by the phosphor, which becomes excited and emits a yellow ray. The viewer perceives an emitted mixture of blue and yellow light (sometimes termed ‘blue shifted yellow’ or ‘BSY’ light) as cool white light.

As an alternative to stimulating a yellow phosphor with a blue LED, another method for generating white emissions involves combined use of red, green, and blue (“RGB”) light emitting diodes in a single package. The combined spectral output of the red, green, and blue emitters may be perceived by a user as white light. Each “pure color” red, green, and blue diode typically has a full-width half-maximum (FWHM) wavelength range from about 15 nm to about 30 nm. Due to the narrow FWHM values of these LEDs (particularly the green and red LEDs), aggregate emissions from the red, green, and blue LEDs exhibit very low color rendering in general illumination applications.

A quantum dot (semiconductor nanocrystallites) is a material, generally semiconductor material, having a crystalline structure only a few nanometers in size, and typically includes about a few hundred atoms to about a few thousand atoms. Because of their small size, quantum dots display unique optical and electrical properties that are different in character to those of the corresponding bulk material. The most immediately apparent of these is the emission of photons under excitation, which are visible to the human eye as light. Quantum dots absorb and emit light at wavelengths determined by their size. Quantum confinement of both the electron and hole in all three dimensions leads to an increase in the effective band gap of the material with decreasing crystallite size. Consequently, both the optical absorption and emission of quantum dots shift to the blue (higher energies) as the size of the dots gets smaller and shift to the red as the size of the dots increase. It has been found that a cadmium selenide (CdSe) quantum dot, for example, can emit light in any monochromatic, visible color, where the particular color characteristic of that dot is dependent only on its size. Dots can even be tuned beyond visible light, into the infra-red or into the ultra-violet. The light emitting characteristics of the quantum dot can be adjusted by controlling the size and composition of the quantum dot, and therefore the quantum dot may be employed in various light emitting devices.

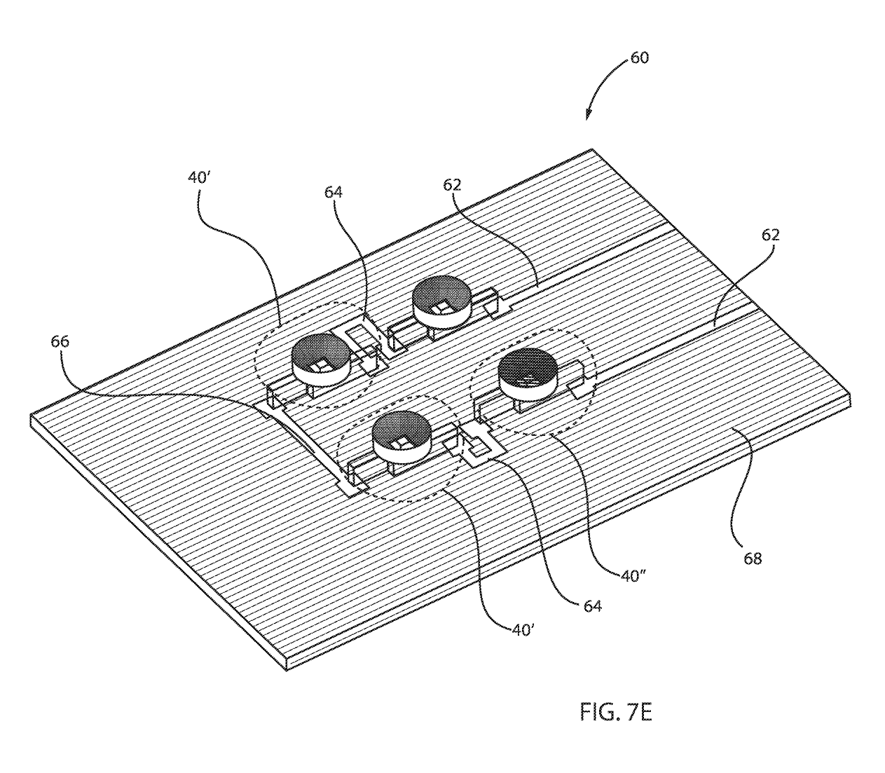

FIG. 8A is a perspective view of conductors attached to a dielectric layer in a first type of configuration, in accordance with an embodiment of the present invention, whereas FIG. 8B is a top view of the conductors of FIG. 8A attached to a dielectric layer in the first type of configuration, where electronic components are attached thereto, in accordance with an embodiment of the present invention.

In various example embodiments, a structure 70 is formed with a dielectric layer 71 flanked between a plurality of first conductive materials 72 and a plurality of second conductive materials 74. The plurality of first conductive materials 72 are formed on one side of the dielectric layer 71, whereas the plurality of second conductive materials 74 are formed on the other side of the dielectric layer 71. The first and second sides of the dielectric layer 71 are in opposed relation to each other. The dielectric layer 71 can include a plurality of openings 78. The plurality of openings 78 can be arranged, e.g., in a series configuration. Of course, the plurality of openings 78 can be arranged in other suitable configurations. In one example, no openings 78 are used. Instead, the conductive materials 72, 74 are connected by a variety of other means (e.g., through pins, crimping, wire bonding, solder, etc.).

The plurality of first conductive materials 72 may be of a first type of configuration and the plurality of second conductive materials 74 may be of a second type of configuration. In one example, the first and second conductive materials 72, 74 can be formed or arranged in parallel rectangular shapes. Stated differently, the plurality of first conductive materials 72 can be, e.g., arranged at a first angle such that the conductors are parallel to each other along an entire first surface of the dielectric layer 71. Similarly, the plurality of second conductive materials 74 can be, e.g., arranged at a second angle such that the conductors are parallel to each other along an entire second surface of the dielectric layer 71. Each of the plurality of first and second conductive materials 72, 74 further includes an opening at a distal end thereof configured to be aligned with respective openings 78 of the dielectric layer 71. Of course, the conductive materials 72, 74 need not be arranged in an angled configuration. Other different shaped conductors may be contemplated.

In one example, as shown in FIG. 8B, at a proximal end of the dielectric layer 71, a first conductive material 72A is arranged to contact a first electrode P2 and a second conductive material 74A is arranged to contact a second electrode N2 of a common electronic component 76A. At a distal end of the dielectric layer 71, the first conductive material 72A extends at an angle to align its opening with an opening 78 of the dielectric layer 71 in region R1. Further, at the distal end of the dielectric layer 71, the second conductive material 74B extends at an angle to align its opening with the opening 78 of the dielectric layer 71 in region R1. Thus, in region R1, distal openings of 72A and 74B are aligned over opening 78 of the dielectric layer 71. Alternatively, the conductive materials 72, 74 may be connected by wires 77. As shown, an example wire 77 can be connected between conductive material 74B and conductive material 72A. Of course, a wire 77 can be used to connect all the conductive materials 72 to the conductive materials 74.

Similarly, in one example, at a proximal end of the dielectric layer 71, a first conductive material 72B is arranged to contact a first electrode P1 and a second conductive material 74B is arranged to contact a second electrode Ni of a common electronic component 76B. At a distal end of the dielectric layer 71, the first conductive material 72B extends at an angle to align its opening with an opening 78 of the dielectric layer 71 in region R3.

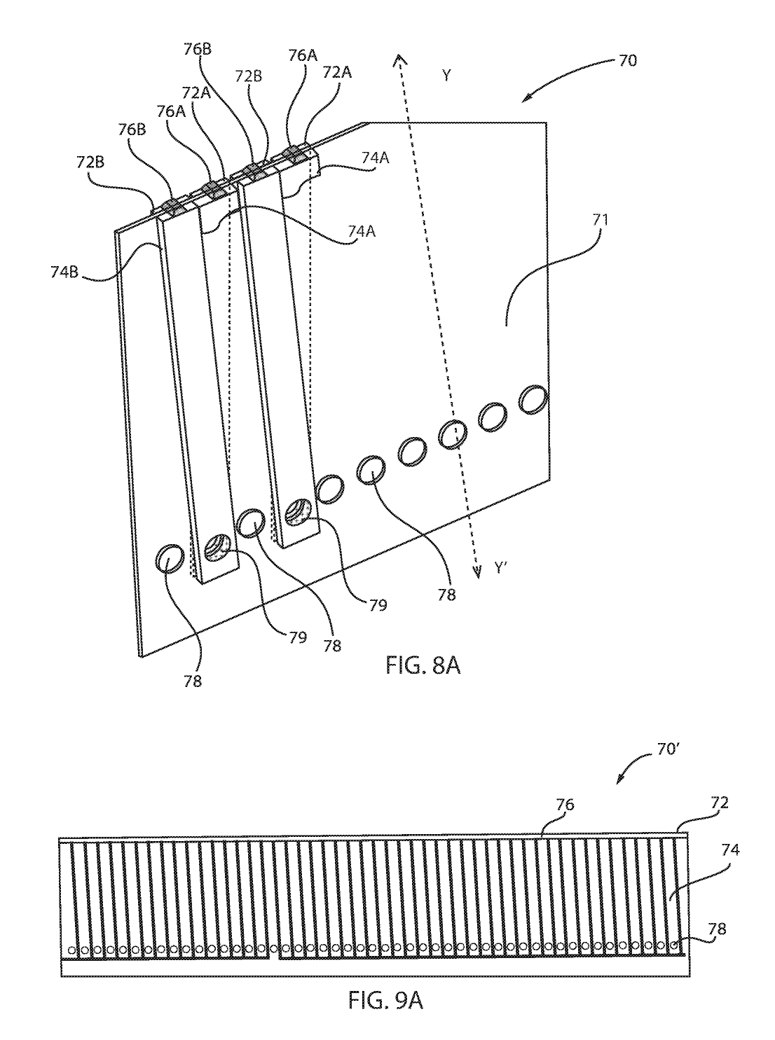

FIG. 9A is a side view of a series of conductors mounted on a dielectric layer in a first type of configuration, in accordance with an embodiment of the present invention.

In various example embodiments, the structure 70′ is shown where the entire second surface of the dielectric layer 71 has been covered with the second conductive material 74. It is noted that the first surface of the dielectric layer 71 has been covered with the first conductive material 72. This configuration of conductive materials 72, 74 allows electrical components 76 to be connected in a series configuration. This series configuration can create edge mounted light emitting devices for a variety of applications.

FIG. 9B is a side view of a series of conductors mounted on a dielectric layer in a first type of configuration, where a bus enables separation of components into one or more groups, in accordance with an embodiment of the present invention.

In various example embodiments, the structure 70″ is shown where the entire second surface of the dielectric layer 71 has been covered with the second conductive material 74. It is noted that the first surface of the dielectric layer 71 has been covered with the first conductive material 72. The structure 70″ differs from the structure 70′ in that a bus 80 is formed. The bus 80 is formed such that it splits the plurality of second conductive materials 74 into one or more groups. In this example, two groups are shown, a first group 82 and a second group 84. The grouping of the chips can be based on design choice to suit, e.g., power supply requirements. Similarly, the bus 80 is formed such that it splits the plurality of first conductive materials 72 into one or more groups (not shown). One skilled in the art may contemplate splitting the conductive materials 72, 74 into a number of different groups. Therefore, multiple strings of electrical components 76 can be grouped together.

FIG. 9C is an enlarged view of a section of the bus, as well as an opening formed on the bus and openings formed on the conductors, in accordance with an embodiment of the present invention.

In various example embodiments, the opening 78 at the bus 80 is shown. The inner surfaces of the first conductive material 72, the second conductive material 74, and the dielectric layer 71 are illustrated. Such inner surfaces of the opening of the bus 80 are not provided (e.g., coated) with any material. In contrast, the openings 78 of the conductive materials 72, 74 are, e.g., provided with a metallic material 79. The metallic material 79 can be, e.g., aluminum, nickel, gold, etc. In one example, no openings 78 are used. Instead, the conductive materials 72, 74 are connected by a variety of other means (e.g., through pins, crimping, wire bonding, solder, etc.).

FIG. 9D is a perspective view of a plurality of structures of FIG. 9B formed in a stacked configuration, in accordance with an embodiment of the present invention.

In various example embodiments, the structure 70″ of FIG. 9B can be formed in a stacked configuration. The dielectric layer could flank each of the stacks or possibly be oriented so that the stack is in series. In other words, multiple structures 70″ can be stacked on top of each other to form a stacked structure. A plurality of electronic components 76 can be aligned upon completion of the stacking structure. The completed stack can have a thickness 75. In the instant case, the thickness represents a stack of three (3) structures 70″. Of course, one skilled in the art can contemplate a number of structures 70″ stacked on top of each other.

FIG. 10 is a perspective view of the structure of FIG. 9B encased within a reflective material structure including a photoluminescent material section, in accordance with an embodiment of the present invention.

In various example embodiments, a structure including a dielectric layer 16 flanked between a first conductive material 12 and a second conductive material 14, where a plurality of electronic components 18 are attached thereon is introduced. The structure is, e.g., encased within, e.g., a reflective material 100. The reflective material 100 includes front and back walls 102 and side walls 104. The reflective material 100 is not limited to the illustrated shape. One skilled in the art may contemplate various geometric configurations for reflective material 100. Alternatively, the reflective cavities can be formed by other methods, such as, but not limited to, injection molding, etc.

The reflective material 100 is configured to form a reflective cavity defined to interface with the electronic components 18. Stated differently, the electronic components 18 are positioned within the reflective cavity, thus creating a linear array of electronic components within the reflective cavity. The reflective cavity can be sealed off by a photoluminescent material 106. The photoluminescent material 106 can have one or more down-converting quantum dots or phosphors (or quantum dot matrix or phosphor matrix). The quantum dots can include, e.g., a protective aluminum oxide shell. In the instant case, the electronic components 18 are all included within a single cavity formed by the reflective material 100, such that all the electronic components 18 are exposed to a, e.g., single photoluminescent material 106. Alternatively, the electronic components 18 can be exposed to a plurality of down-converting materials dispersed in the matrix, e.g., green QDs, red QDs, or additional wavelengths, or phosphors.

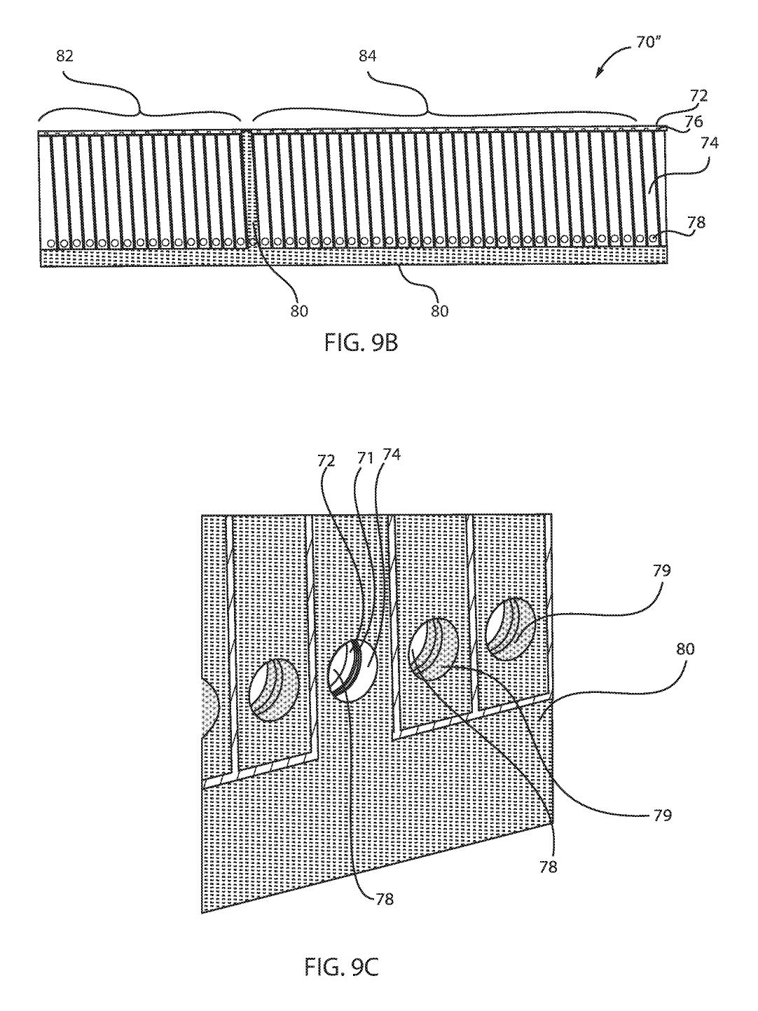

FIG. 11 is a perspective view of the structure of FIG. 10 in communication with a light guide, in accordance with an embodiment of the present invention.

In various example embodiments, a light guide 110 can be interfaced with the light emitting surface of the structures described herein encased within the reflective material 100.

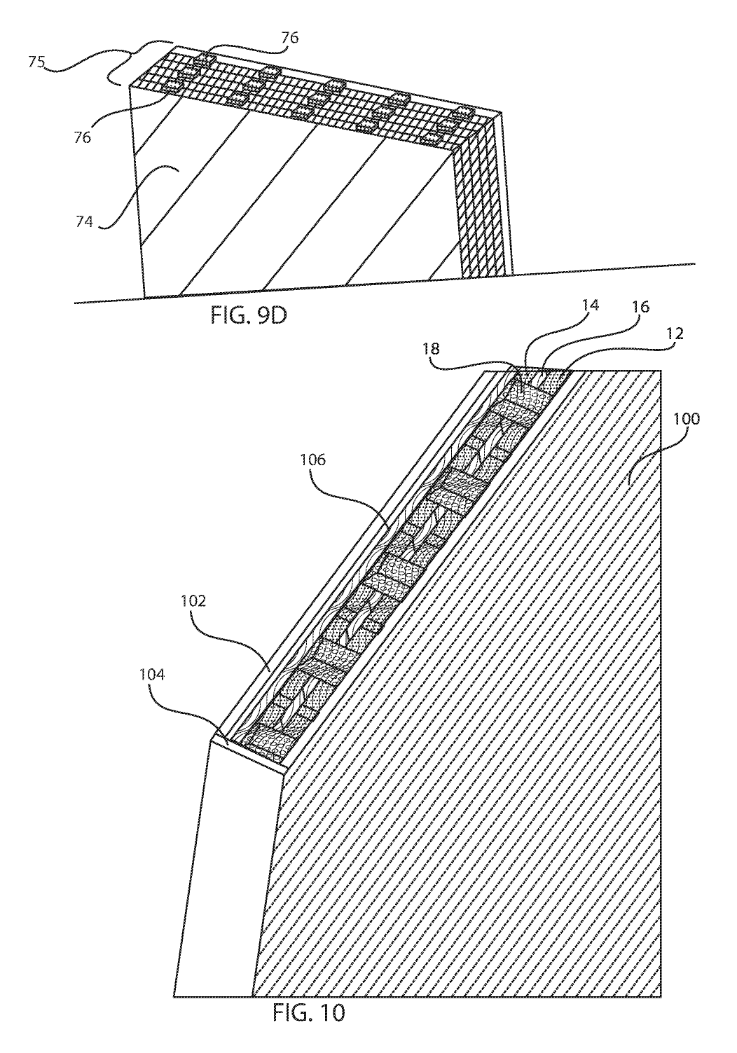

FIG. 12 is a top view of the structure of FIG. 10 where a plurality of reflective cavities are formed to separate the components from each other to produce a plurality of colors without cross talk, in accordance with an embodiment of the present invention.

In various example embodiments, the reflective material 100 can include front and back walls 102, side walls 104, as well as a plurality of reflector divider walls 112. The divider walls 112 can be placed between the plurality of electronic components 18. Thus, each electronic component 18 can be isolated within its own reflector cavity.

This configuration 120 allows for a plurality of reflector cavities to be formed with separated monochromatic colors in an array. This configuration 120 allows each electronic component 18 to be associated with a respective photoluminescent material. For example, one electronic component 18 is associated with photoluminescent material 121, another electronic component 18 is associated with photoluminescent material 123, another electronic component 18 is associated with photoluminescent material 125, and another electronic component 18 is associated with photoluminescent material 127.

The first photoluminescent material 121 can be configured to allow its respective electronic component 18 to emit, e.g., a red light. The second photoluminescent material 123 can be configured to allow its respective electronic component 18 to emit, e.g., a green light. The third photoluminescent material 125 can be configured to allow its respective electronic component 18 to emit, e.g., a yellow light. The fourth photoluminescent material 127 can be configured to allow its respective electronic component 18 to emit, e.g., a blue light. Therefore, each reflective cavity can have or produce a separate color. This configuration 120 prevents cross talk between colors, thus reducing system inefficiencies. In addition, each reflective cavity (or cell) can produce light of a different wavelength, which is then emitted into either ambient environments or in a light guide 110 (FIG. 11). It is contemplated that the produced colors can mix in the light guide 110 or in the ambient environment.

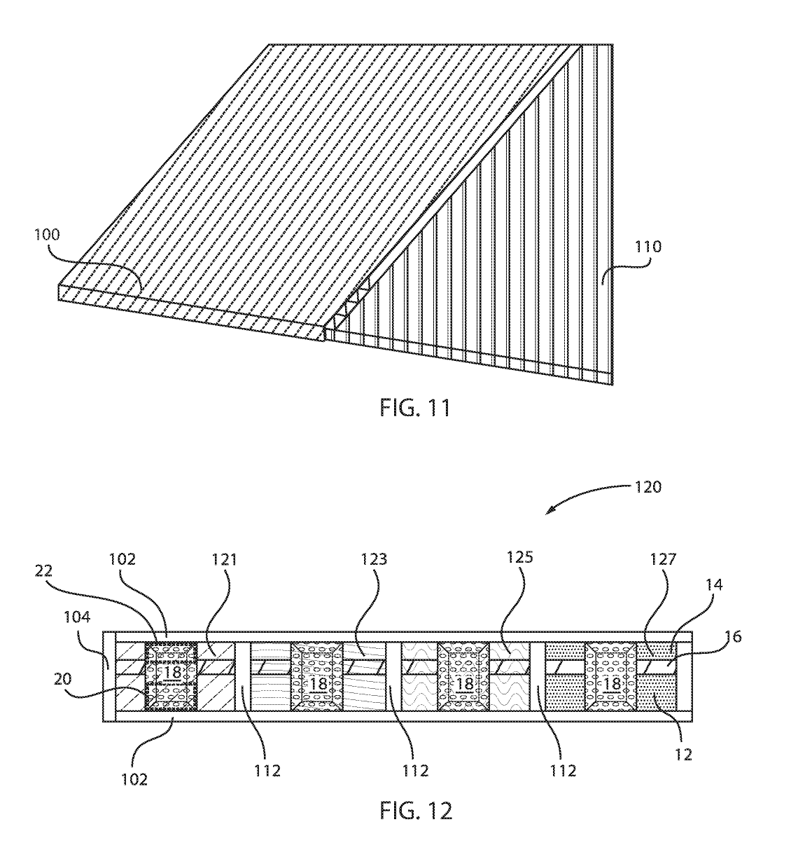

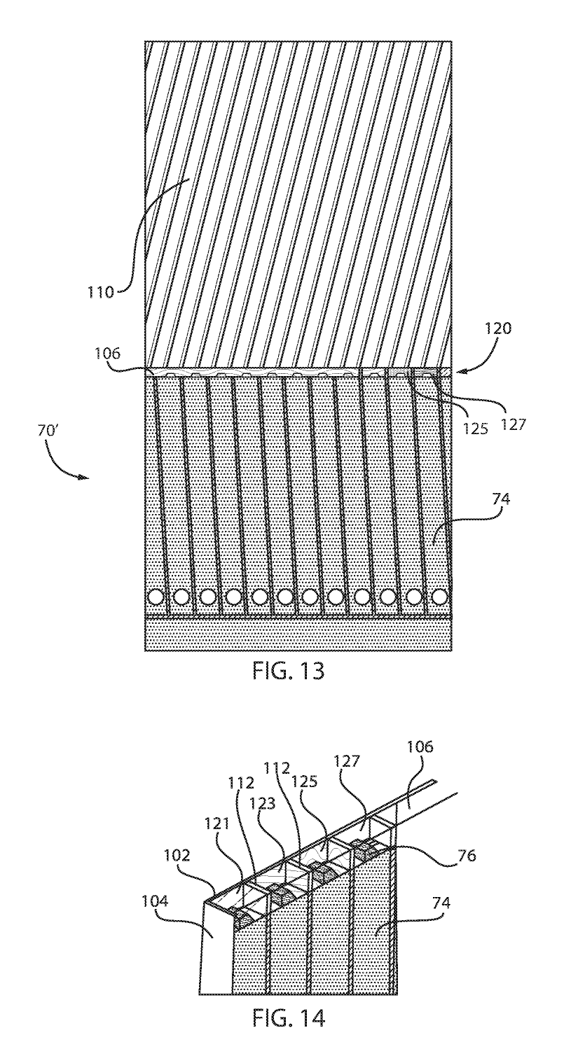

FIG. 13 is a top view of the structure of FIG. 12 where the plurality of reflective cavities are attached to a light guide, in accordance with an embodiment of the present invention, whereas FIG. 14 is a perspective, cut-away view of the structure of FIG. 12 where each of the plurality of reflective cavities includes a component for generating different colors without cross talk, in accordance with an embodiment of the present invention.

In various example embodiments, the light guide 110 interfaces with the structure 70′ of FIG. 9B. At the interface section, the configuration of FIG. 10 is illustrated on the left-hand side, whereas the configuration 120 of FIG. 12 is illustrated on the right-hand side. Thus, the structure 70′ can be formed with electronic components 18 that are positioned within a common reflective cavity and with electronic components 18 that are formed within individual (or separate and distinct) reflective cavities. The electronic components 18 on the left-hand side are bundled together and associated with reflective material 106 (to produce a single color), whereas electronic components 18 on the right-hand side are individually positioned within respective reflective cavities to produce a plurality of different colors. Therefore, one or more down-converting substances can be used to produce different wavelengths (different colors).

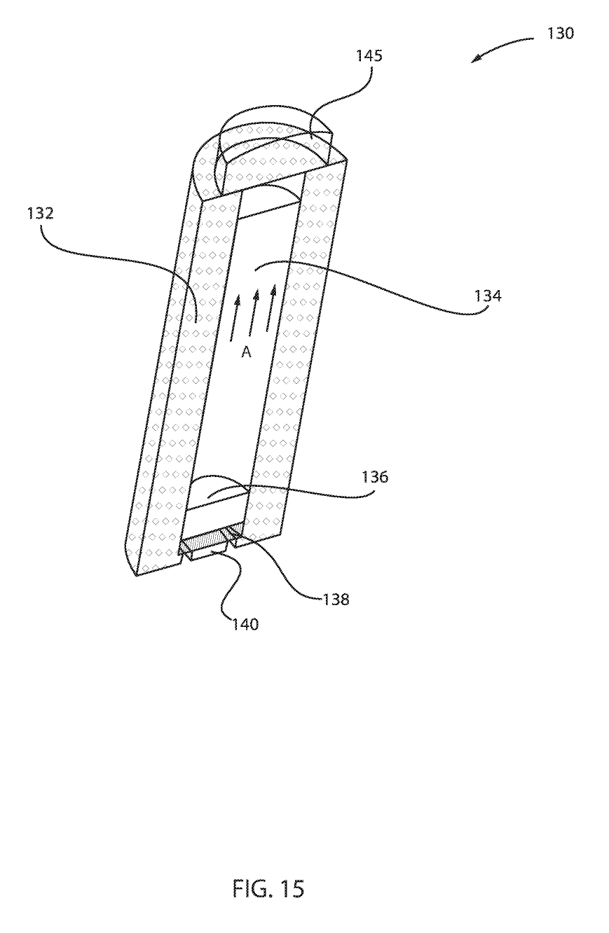

FIG. 15 is a perspective view of an example optical structure, in accordance with an embodiment of the present invention.

In various example embodiments, an optical structure 130 can be used. The optical structure can be referred to as a reflector 130. The reflector 130 defines a reflector cavity 132. The reflector cavity 132 can include a photoluminescent material 134. The photoluminescent material 134 can be, e.g., a quantum dox matrix or a phosphor matrix. The quantum dot matrix can include, e.g., a protective aluminum oxide shell. An optical dichroic filter 136 can be positioned at a distal end of the reflector cavity 132 and the distal end of the quantum dot matrix 134. An optical silicone 138 (or other optically transmissive material) can be positioned adjacent the optical dichroic filter 136. An electronic component 140 can be attached adjacent the optical silicone 138. The electronic components 140 can be a light emitting device. The light emitting device can be, e.g., an LED or a plurality of LEDs. The proximal end of the reflector 130 can include a lens 145. The reflector cavity 132 enables emission of light to be directed in one direction, indicated by arrows “A,” that is, toward the lens 145. The optical dichroic filter 136 blocks any light going in the direction of the electronic components 140. Thus, a higher intensity beam of light can be directed toward the lens 145. The dichroic filter 136 is a thin-film filter or an interference filter that is a very accurate color filter used to selectively pass light of a small range of colors while reflecting other colors.

This is only one non-limiting example of an optical structure 130. One skilled in the art may contemplate forming a number of different optical structures having different geometric configurations and including a number of different components therein. The exemplary embodiments of the present invention are not limited to this type of optical structure of FIG. 15. For example, the reflector cavities can be multi-sided with a plurality of sides and aspect ratios. Shapes can be asymmetrical. Shapes can also be tapered of have curved side walls. Shapes can be oriented in an array of rows and columns or other pattern of repeating cavity shapes. Each opening can accommodate one or more light emitting devices, such as LEDs. The reflector cavities can be formed from a variety of materials to cause different reflectivity.

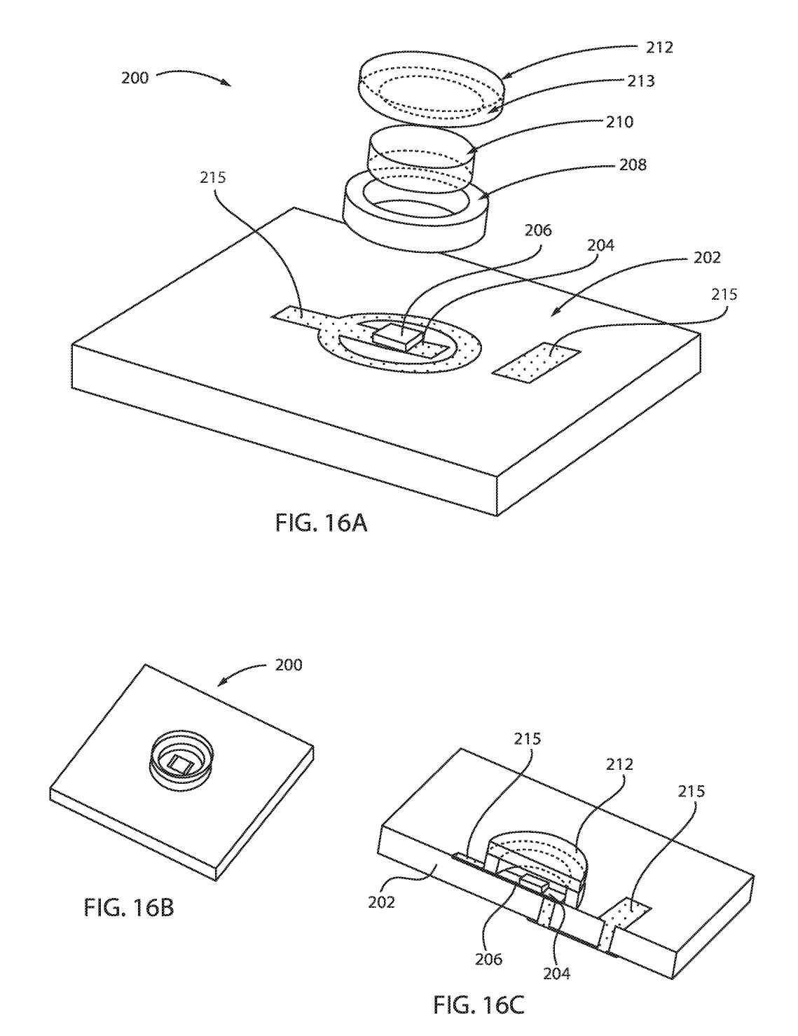

FIG. 16A is an exploded view of a hermetically sealed quantum dot dispersed in an optically transmissive material, in accordance with an embodiment of the present invention.

FIG. 16B is a perspective assembled view of the hermetically sealed quantum dot dispersed in an optically transmissive material of FIG. 16A, in accordance with an embodiment of the present invention.

FIG. 16C is a cross-sectional view of the hermetically sealed quantum dot dispersed in an optically transmissive material, in accordance with an embodiment of the present invention.

Quantum dots are particularly sensitive to oxygen, moisture, and heat. In the exemplary embodiments of FIGS. 16A-16C, a method for hermetically sealing the quantum dots dispersed in an optically transmissive material is introduced. The optically transmissive material can be, e.g., acrylic, silicone or other polymers.

The hermetic seal system 200 includes a substrate 202 for mounting a light emitting device 206 via a pad 204. The light emitting device 206 can be, e.g., an LED. The matrix of quantum dots 210 may contain one or more quantum dots of different output wavelengths (colors) dispersed. The quantum dot matrix 210 can be coupled to the light emitting device 206 and the substrate 202. The hermetic seal 212 can include a glass section 213. The hermetic seal 212 is attached to the quantum dot matrix 210 via the glass section 213 by, e.g., bonding, welding, soldering, etc. The reflective cavity 208 can be, e.g., bonded, welded, soldered or brazed to the substrate 202. This construction allows for complete encapsulation of the quantum dot matrix 210 within the hermetic seal 212, which serves as an oxygen/moisture sealed cavity. However, light can be transmitted through the glass section 213. The substrate 202 can be, e.g., a metallized ceramic or other type of circuit board, which allows for hermetically sealing of the quantum dot matrix 210. The pad 204 can be connected to traces 215 that extend beyond the reflective cavity 208. The traces 215 can be directed through the substrate in the z-axis and connected to another circuit layer. One of the traces 215 can be connected to the reflective cavity 208. The reflective cavity 208 can be mounted on a bonding pad to create the hermetic seal and also allow for electrical connection to the chip and any outside circuit trace.

In summary, by directly coupling the electronic components (or LEDs), less heat can be generated and better heat dissipation can be achieved for integrated circuit packages. The exemplary embodiments of the present invention basically form a novel heat sink with interconnects.

It is to be understood that the present invention will be described in terms of a given illustrative architecture; however, other architectures, structures, substrate materials and process features and steps/blocks can be varied within the scope of the present invention.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. 1t will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

Having described preferred embodiments of a method of device fabrication and a semiconductor device thereby fabricated for dissipating heat through quantum dot optics and light emitting diode (LED) integration (which are intended to be illustrative and not limiting), it is noted that modifications and variations can be made by persons skilled in the art in light of the above teachings. It is therefore to be understood that changes can be made in the particular embodiments described which are within the scope of the invention as outlined by the appended claims. Having thus described aspects of the invention, with the details and particularity required by the patent laws, what is claimed and desired protected by Letters Patent is set forth in the appended claims.

What is claimed is:

1. A method of forming a structure for dissipating heat, the method comprising:
forming a first conductive material;
forming a dielectric layer over the first conductive material;
forming a second conductive material over the dielectric layer such that the first and second conductive materials are coplanar along a longitudinal axis defined by a mounting surface of the first and second conductive materials; and
attaching an electronic component to the mounting surface of the first and second conductive materials such that a first electrode of the electronic component electrically contacts the first conductive material and a second electrode of the electronic component electrically contacts the second conductive material.

2. The method of claim 1, further comprising coupling one or more conducting layers to the mounting surface of the first and second conductive materials before attaching the electronic component thereto.

3. The method of claim 1, wherein the electronic component is one or more light emitting devices.

4. The method of claim 1, wherein, in an assembled state, to enable electrification of the electronic component, the first conductive material includes one or more first interconnects and the second conductive material includes one or more second interconnects.

5. The method of claim 1, further comprising offsetting the first conductive material from the second conductive material along the mounting surface.

6. The method of claim 5, further comprising forming a reflective cavity surrounding the electronic component and including a photoluminescent material within an inner surface of the reflective cavity, the photoluminescent material being hermetically sealed within the reflective cavity.

7. The method of claim 6, wherein the photoluminescent material has one or more down-converting quantum dots or phosphors.

8. The method of claim 7, wherein the quantum dots include a protective aluminum oxide shell.

9. The method of claim 1, further comprising encasing the structure with a reflective material such that a reflective cavity is defined to interface with the electronic component, the reflective cavity including a photoluminescent material having one or more down-converting quantum dots or phosphors.

10. The method of claim 9, further comprising integrating a light guide with the reflective material encasing the structure.

11. A method of forming a structure for dissipating heat, the method comprising:
forming a dielectric layer;
forming a plurality of first conductive materials defining a first type of configuration on a first side of the dielectric layer;
forming a plurality of second conductive materials defining a second type of configuration on a second side of the dielectric layer, where the second type of configuration is different than the first type of configuration; and
attaching an electronic component to each of the plurality of first and second conductive materials such that a first electrode of the electronic component electrically contacts a first conductive material and a second electrode of the electronic component electrically contacts a second conductive material on opposed ends of the dielectric layer.

12. The method of claim 11, wherein each of the plurality of first conductive materials includes a first opening and each of the plurality of second conductive materials includes a second opening such that the first and second openings align with an opening of the plurality of openings of the dielectric layer.

13. The method of claim 12, wherein inner surfaces defined by the first opening, the second opening, and the opening of the dielectric layer include a conductive material.

14. The method of claim 11, wherein a bus is formed adjacent the dielectric layer such that the plurality of first conductive materials are separated into one or more first groups and the plurality of second conductive materials are separated into one or more second groups.

15. The method of claim 11, wherein the electronic component is one or more light emitting devices.

16. The method of claim 11, further comprising encasing the structure with a reflective material such that a reflective cavity is defined to interface with the electronic component attached to each of the plurality of first and second conductive materials, the reflective cavity including a photoluminescent material, the photoluminescent material being hermetically sealed within the reflective cavity.

17. The method of claim 16, wherein the photoluminescent material has one or more down-converting quantum dots or phosphors.

18. The method of claim 17, wherein the quantum dots include a protective aluminum oxide shell.

19. The method of claim 11, further comprising encasing the structure with a reflective material such that each electronic component is associated with a reflective cavity, each reflective cavity including a different photoluminescent material for production of a plurality of different colors.

20. The method of claim 19, further comprising integrating a light guide with the reflective material encasing the structure.

21. A structure for dissipating heat, the structure comprising:
a first conductive material;
a dielectric layer formed over the first conductive material;
a second conductive material formed over the dielectric layer such that the first and second conductive materials are coplanar along a longitudinal axis defined by a mounting surface of the first and second conductive materials; and
an electronic component attached to the mounting surface of the first and second conductive materials such that a first electrode of the electronic component electrically contacts the first conductive material and a second electrode of the electronic component electrically contacts the second conductive material.

22. The structure of claim 21, wherein the electronic component is one or more light emitting devices.

23. The structure of claim 21, further comprising encasing the structure with a reflective material such that a reflective cavity is defined to interface with the electronic component attached to each of the plurality of first and second conductive materials, the reflective cavity including a photoluminescent material, the photoluminescent material being hermetically sealed within the reflective cavity.

24. The structure of claim 23, wherein the photoluminescent material has one or more down-converting quantum dots or phosphors.

25. The structure of claim 24, wherein the quantum dots include a protective aluminum oxide shell.

26. The structure of claim 21, further comprising encasing the structure with a reflective material such that each electronic component is associated with a reflective cavity, each reflective cavity including a different photoluminescent material for production of a plurality of different colors, the different photoluminescent materials being hermetically sealed within their reflective cavity.
